(19) United States
(12) Patent Application Publication
(10) Pub. No.: US 2016/0013614 A1
(43) Pub. Date: Jan. 14, 2016

(54) LASER DRIVER AND OPTICAL MODULE INCLUDING SAME

(71) Applicant: SUMITOMO ELECTRIC INDUSTRIES, LTD., Osaka (JP)

(72) Inventor: Akihiro MOTO, Yokohama-shi (JP)

(73) Assignee: SUMITOMO ELECTRIC INDUSTRIES, LTD., Osaka (JP)

(21) Appl. No.: 14/798,187

(22) Filed: Jul. 13, 2015

(30) Foreign Application Priority Data
Jul. 14, 2014 (JP) 2014-143916

(51) Int. Cl. H01S 5/022; H01S 5/042

(52) U.S. Cl. CPC H01S 5/02248; H01S 5/0427

(57) ABSTRACT

A laser driver drives a laser diode by increasing and decreasing a drive current by a differential signal having a pair of positive phase and negative phase components and comprises an upper voltage-controlled current, source increasing the drive current responding to an increase of the positive phase component of the differential signal, a lower voltage-controlled current source for decreasing the drive current responding to an increase of the negative Phase signal of the differential signal, and an output terminal, connected to output terminals of the voltage-controlled current sources, for outputting the drive current. The voltage-controlled current source has a band-pass filter with a gain for the positive phase component set greater in a predetermined frequency region than in a frequency region other than the predetermined frequency region.

### BACKGROUND OF THE INVENTION

1. Field of the Invention

The present invention relates to a laser driver and an optical module including the same.

2. Related Background Art

Optical transceivers for transmitting and receiving optical signals and interconversion between the optical signals and electrical signals have been used in optical transmission systems constituting core networks and in communication lines between severs in data centers. Such an optical transceiver has a transmitter part (optical transmitter) and a receiver part (optical receiver) in general. The optical transmitter converts an electric signal into an optical signal and sends the optical signal to an optical transmission line including an optical fiber. Specifically, an optical transmitter of a “direct modulation” type incorporates therein a light-emitting element (laser diode) for generating an optical signal and a laser driver for driving the laser diode by a drive current.

For the optical transceivers, common specifications, called MSA (Multi Source Agreement) such as XFP (10 Gigabit Small Form-factor Pluggable), QSFP+ (Quad Small Form-factor Pluggable Plus), and GYP (C Form-factor Pluggable), have been defined, so as to set up standards for electrical and optical characteristics, communication interfaces with host devices for monitoring and controlling, terminal arrangements, outer forms (form factors), and the like. Recent steep growth in communication traffic has been demanding to increase transmission rate of the optical signals from 10 Gbps to 25 Gbps and further to 40 Gbps. For responding to such a demand, shunt drivers and push-pull drivers have been incorporated into the optical transmitters for high-speed operations.

When the conventional laser driver used for direct modulation directly drives a laser diode at a high transmission rate exceeding 20 Gbps, however, the frequency characteristic of the laser diode may have a depression in some frequency components. Such a depression often deteriorates the group delay of the optical signal emitted from the laser diode, thereby increasing jitters in the optical signal.

In view of such a problem, an object of the present invention is to provide a laser driver which restrains jitters in the optical signal and an optical module including the same.

### SUMMARY OF THE INVENTION

For solving the above-mentioned problem, the laser driver in accordance with one aspect of the present invention is a laser driver for driving a laser diode (LD) by a differential signal having a pair of positive phase and negative phase components. The laser driver comprises an output terminal configured to be connected to an anode of the LD, a first circuit configured to generate a first modulation current from the positive phase component of the differential signal and provide the first modulation current to the anode of the LID through the output terminal, a second circuit configured to generate a second modulation current from the negative phase component of the differential signal and provide the second modulation current to the anode of the LD through the output terminal. The first circuit includes a frequency compensator which boosts frequency components of the positive phase component within a predetermined frequency region.

The optical module in accordance with another aspect of the present invention comprises a laser diode (LD) configured to convert a drive current to an optical signal, the laser driver having the output terminal connected to an anode of the LD. The first modulation current increasing the drive current and the second modulation current decreasing the drive current.

### BRIEF DESCRIPTION OF THE DRAWINGS

FIG. 1 is a diagram illustrating a schematic structure of an optical module in accordance with a preferred embodiment of the present invention;

FIG. 2 is a circuit diagram illustrating a detailed structure of the optical module 1 of FIG. 1;

FIG. 3 is a graph illustrating electrical-to-optical response on a positive phase component and a negative phase component of a driving signal regarding the optical module 1 in accordance with the embodiment and an optical module 901 in accordance with a comparative example;

FIG. 4 is a graph illustrating electrical-to-optical response obtained by combining each of the responses of the positive phase component and negative phase component together regarding the optical module 1 in accordance with the embodiment and the optical module 901 in accordance with the comparative example;

FIG. 5A and FIG. 5B are graphs illustrating results of simulation of the electrical-to-optical response and optical waveform in a typical laser diode;

FIG. 6 is a circuit diagram illustrating the structure of an optical module 1A in accordance with a modified example of the present invention;

FIG. 7 is a circuit diagram illustrating the structure of an optical module 1B in accordance with a modified example of the present invention;

FIG. 8 is a circuit diagram illustrating an example of the structure of a voltage source 5 in FIG. 1;

FIG. 9 is a circuit diagram illustrating a detailed structure of the optical module 901 in accordance with the comparative example;

FIG. 10A is a graph illustrating an electrical-to-optical response in a typical laser diode; and

FIG. 10B is a graph illustrating an electrical-to-optical response in a laser diode including a conventional driver.

### DESCRIPTION OF THE PREFERRED EMBODIMENTS

In the following, an optical module in accordance with a preferred embodiment of the present invention will be explained in detail with reference to the accompanying drawings. In the explanation of the drawings, the same constituents will be referred to with the same signs while omitting their overlapping descriptions.

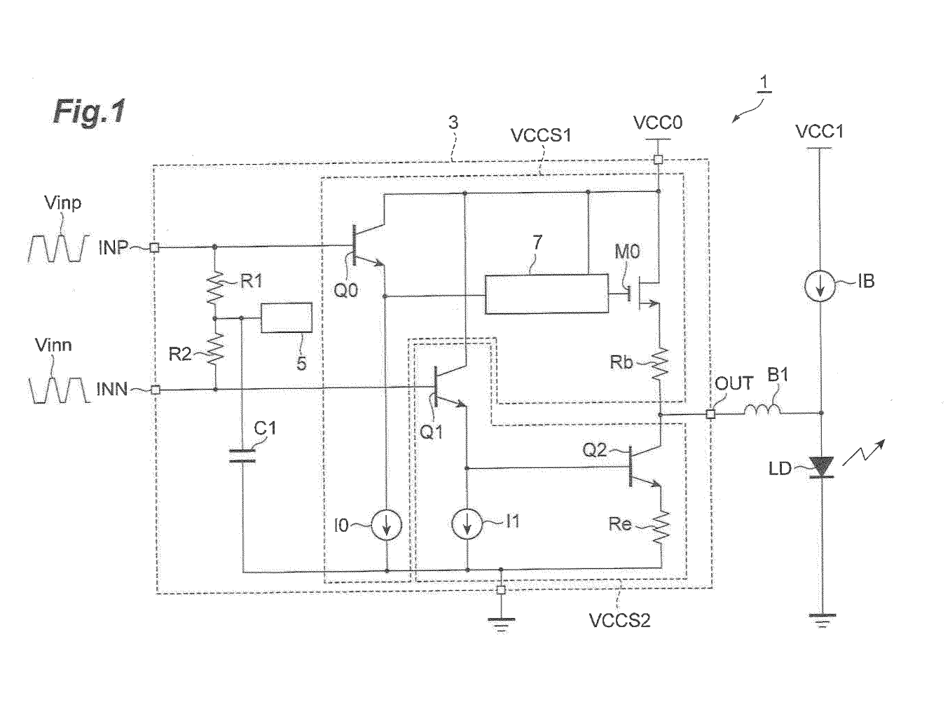

An optical module 1 in accordance with this embodiment is a TOSA (Transmitter Optical Sub-Assembly) which outputs an optical signal in response to an electric signal input from an external device. The optical module 1 includes a driver 3 for driving a laser diode (LD) by a push-pull driving-technique. FIG. 1 illustrates a schematic structure of the optical module 1.

As illustrated in this drawing, the optical module 1 mainly comprises a laser diode LD and the driver 3. An example of laser diode LD is a distributed-feedback laser diode. The driver 3 supplies a modulation current to the laser diode LD by push-pull operations described below. The laser diode LD has a cathode (negative electrode) connected to a ground and an anode (positive electrode) connected to a voltage VCC1 through a current source TB. As a consequence, the laser diode LD is supplied with a DC bias current Ibias, which is automatically maintained constant by an APC (Automatic Power Control) circuit (not depicted)An output terminal OUT of the driver 3 is connected to the anode of the laser diode LID through a bonding wire B1. In such a structure, a drive current to drive the laser diode LD is determined by the current source IB and the driver 3. The driving current is input to the anode of the laser diode LD. The laser diode LD outputs an optical signal in response to the drive current supplied.

The driver 3, which includes voltage-controlled current sources(first and second circuit) VCCS1, VCCS2, increases and decreases the drive current for the direct modulation responding to a differential input signal having a pair of positive phase and negative phase signals (positive phase and negative phase components) from the outside. The voltage-controlled current source VCCS1 is connected between an input terminal INP and the output terminal OUT. The voltage-controlled current source VCCS1 generates a modulation current Ip in response to a positive phase signal Vinp (the positive phase component of the differential input signal) input through the input terminal INP. The modulation current Ip is pushed out toward the laser diode LD through the bonding wire B1. The voltage-controlled current source VCCS2 is connected between an input terminal INN and the output terminal OUT. The voltage-controlled current source VCCS2 generates a current In in response to a negative phase signal Vinn (the negative phase component of the differential input signal) input through the input terminal INN. The current In is pulled in from the laser diode LD through the bonding wire B1.

The driver 3 generates a drive current ILD to drive the laser diode LD by superimposing the modulation currents Ip and In with the bias current Ibias. Therefore, the drive current ILD equals the bias current Ibias plus the modulation current Ip minus the modulation current In (where a positive current corresponds to a current flowing from the output terminal OUT to the laser diode and a negative current corresponds to a current flowing from the laser diode to the output terminal OUT). In other words, the voltage-controlled current source VCCS1 increases the drive current ILD as the positive phase signal Vinp increases, and the voltage-controlled current source VCCS2 decreases the drive current IUD as the negative phase signal Vinn increases. These modulation currents Ip, In directly modulate the laser diode LD to which the bias current Ibias is constantly applied. Thus, the driver 3 pushes the modulation current Ip into a load circuit (laser diode LD and pull the current In from the load circuit (laser diode LD) complementarily depending on the differential input signal. Such complementary driving operations are referred to as push-pull operations, and a driver for driving the load circuit (laser diode LD) by the push-pull operations according to an input signal is called a push-pull driver.

The structure of the driver 3 will now be explained in more detail.

The input terminals INP is connected to a termination node through a terminator R1 and the input terminal INN is also connected to the termination node through a terminator R2. Each of the terminators R1, R2 has a resistance value of 50 for example. The termination node is grounded through a capacitor C1 in order to lower common-mode impedance and biased to a reference potential Vref0 by a voltage source 5.

The voltage-controlled current source VCCS1 is constituted by an NPN bipolar transistor Q0, a current source I0, a bandpass filter (frequency compensator) 7, an nMOS transistor (n-type Metal-Oxide-Semiconductor Field-Effect Transistor) M0 which is an n-type field-effect transistor, and a resistor Rb. The NPN bipolar transistor Q0 has a base connected to the input terminal INP, an emitter grounded through the current source I0, and a collector connected to a supply voltage VCC0. The emitter of the NPN bipolar transistor Q0 is also connected to a gate of the nMOS transistor M0 through the bandpass filter 7. The nMOS transistor M0 has a drain connected to the supply voltage VCC0 and a source connected to the output terminal OUT through the resistor Rb.

In the voltage-controlled current source VCCS1, the emitter follower constituted by the NPN bipolar transistor Q0 receives the positive phase signal Vinp, while the output of the emitter follower VCCS1 is input to the gate of the nMOS transistor M0 through the bandpass filter 7. The gate of the nMOS transistor M0 is further connected to the supply voltage VCC0 through a resistor Ra (which will be explained later) within the bandpass filter 7. The nMOS transistor M0 and resistor Rb output the modulation current Ip toward the output terminal OUT according to the positive phase signal Vinp. That is, the modulation current Ip increases with the positive phase signal Vinp. Here, the bandpass filter 7 makes the frequency components of the positive phase signal VinP in a predetermined frequency region pass through and suppress the other frequency components outside of the predetermined frequency region. As a result, the frequency response of the modulation current Ip with respect to the differential input signal is boosted in the predetermined frequency region.

The voltage-controlled current source VCCS2 is constituted by an NPN-bipolar transistor Q1, a current source I1, an NPN bipolar transistor Q2, and a resistor Re. The NPN bipolar transistor Q1 has a base connected to the input terminal INN, an emitter grounded through the current source I1, and a collector connected to the supply voltage VCC0. The emitter of the NPN bipolar transistor Q1 is also connected to a base of the NPN bipolar transistor Q2. The NPN bipolar transistor Q2 has a collector connected to the output terminal OUT and an emitter grounded through the resistor Re.

In the voltage controlled current source VCCS2, the base of the NPN bipolar transistor Q2 is biased to a bias potential determined by the voltage source 5 through the terminator R2 and an emitter follower constituted by the NPN bipolar transistor Q1. Letting Ib1 be the base current of the NPN bipolar transistor Q1, and Vbe1 be the base-emitter voltage, for example, the bias voltage is Vref0-R2*Ib1-Vbe1. The collector of the NPN bipolar transistor Q2 is biased to the on-state voltage of the laser diode LD. The negative phase signal Vin is received by the emitter follower constituted by the NPN bipolar transistor Q1, and the output of the emitter follower is input to the base of the NPN bipolar transistor Q2. The NPN bipolar transistor Q2 and the resistor Re pull in the current In from the output terminal OUT according to the negative phase signal Vinn. That is, the current In increases with the negative phase signal Vinn.

The gain for the negative phase signal Vinn in the voltage-controlled current source VCCS2 is set greater than the gain for the positive phase signal Vinp in the voltage-controlled current source VCCS1. The following is a reason therefor. That is, while it is necessary to decrease the resistance of the resistor Rb in order to increase the gain on the voltage-controlled current source VCCS1, when the resistance is set too low, the output resistance of the voltage-controlled current source VCCS1 becomes comparable to the impedance of the laser diode LD. As the resistance of the resistor Rb can be seen in parallel with the impedance of the laser diode LD from the voltage-controlled current source VCCS2, the current In is harder to flow to the laser diode LD (some component of the current In is pulled in from the voltage-controlled current source VCCS1). At the same time, a plurality of parasitic capacitances Cgd, Cds, and Cdb (drain-body capacitance) of the nMOS transistor M0 become more influential, so that they deteriorates the electrical-to-optical response in a high frequency region and so the high-speed performance of the optical module 1. Setting a greater gain for the voltage-controlled current source VCCS2 prevents such a disadvantageous state.

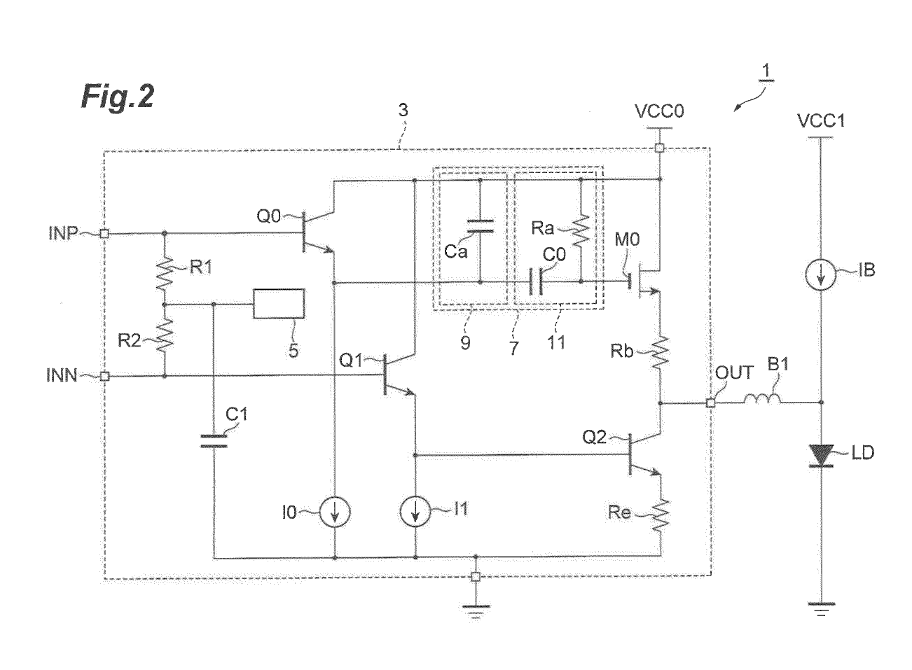

FIG. 2 illustrates a detailed circuit structure of the bandpass filter 7 of FIG. 1. The bandpass filter 7 illustrated in the drawing includes a low-pass filter (first filter) 9 and a high-pass filter (second filter) 11. The low-pass filter (first filter) 9 is constituted by a capacitor Ca and increases its gain at a frequency lower than a predetermined frequency (first frequency, an example of which is about 10 GHz). The high-pass filter (second filter) I1 is constituted by a capacitor C0 and the resistor Ra and increases its gain at a frequency higher than a predetermined frequency (second frequency, an example of which is about 2 GHz). The bandpass filter 7 needs that the first frequency is higher than the second frequency. Specifically, one end of the capacitor Ca is connected to the output of the emitter follower constituted by the NPN bipolar transistor Q0 and the other end of the capacitor Ca is connected to the supply voltage VCC0. Additionally, the capacitor C0 is connected between the output of the emitter follower constituted by the NPN bipolar transistor Q0 and the gate of the nMOS transistor M0, and one end of the resistor Ra is connected to the gate of the nMOS transistor M0 and the other end of the resistor Ra is connected to the supply voltage VCC0. For the capacitor Ca, the capacitance thereof is selected to be 2 pF, for example. For the capacitor C0, the capacitance thereof is selected to be 800 fF, for example. For resistor Ra, the resistance thereof is selected to be 100 Ω, for example. The term gain is used herein for explaining frequency characteristics of filters, but does not necessarily mean that signals are amplified by the filters. A low-pass filter having a greater gain in the low frequency region lower than a given frequency (cut-off frequency) and a smaller gain in the high frequency region higher than the given frequency is considered to be practically equivalent to a low-pass filter having a smaller loss in the low frequency region and a larger loss in the high frequency region as long as signal can go through the filter with a small attenuation. That is, to increase gain is considered herein to include to decrease attenuation (negative gain) in a broad sense. Therefore, the bandpass filter may be a filter in which the attenuation of a signal in a predetermined frequency range is smaller than that of a signal outside of the predetermined frequency range. The low-pass filters and bandpass filters may be active filters using active elements such as transistors having actual gains; in this case, it is sufficient for a gain to be set greater in a predetermined frequency range than outside of the frequency range.

In this bandpass filter 7, the output impedance of the emitter follower and the capacitor Ca form a low-pass filter, the capacitor C0 and the resistor Ra form a high-pass filter, and these filters are combined together so as to constitute a bandpass filter. That is, it is constructed such that the positive phase signal Vinp input from the input terminal INP passes the low-pass filter unit 9 and then the high-pass filter unit 11. This can make a gain greater in a frequency region between the frequency (second frequency) set by the high-pass filter unit 11 and the frequency (first frequency) set by the low-pass filter unit 9 than in the other frequency regions.

The driver 3 explained in the foregoing increases and decreases the drive current for the laser diode LD as the positive phase signal Vinp and negative phase signal Vinn increase, respectively. Here, the voltage-controlled current source VCCS1 for controlling the drive current according to the positive phase signal Vinp is equipped with the bandpass filter 7, which makes the gain for the positive phase signal Vinp in the voltage-controlled current source VCCS1 greater in a predetermined frequency region than in a frequency region other than the predetermined frequency region. As a result, the frequency characteristic of the electrical-to-optical response of the laser diode LD can be compensated and made flatter by the bandpass filter 7. This can improve the group delay of optical output signals generated by the laser diode LD and reduce jitters in the optical signals.

The bandpass filter 7, which includes the low-pass filter 9 and high-pass filter 11, is constructed such that the positive phase component Vinp passes the low-pass filter 9 and then the high-pass filter unit 11. Such a structure can make the gain for the positive phase signal Vinp in the voltage-controlled current source VCCS1 greater in the predetermined frequency region by a simple circuit configuration.

In the following, the electrical-to-optical response in this embodiment will be explained, in comparison with a comparative example.

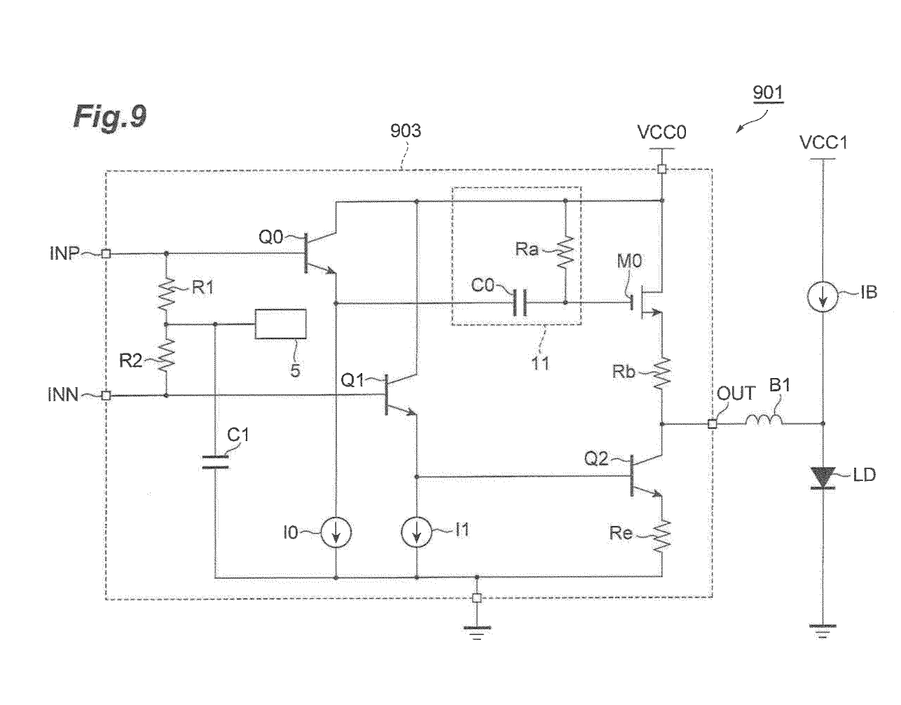

FIG. 9 illustrates a detailed structure of an optical module 901 in accordance with the comparative example. This optical module 901 differs from the optical module 1 in accordance with the embodiment in that it comprises the high-pass filter 11 alone between the output of the emitter follower constituted by the NPN bipolar transistor Q0 and the gate of the nMOS transistor M0 and is devoid of the low-pass filter 9.

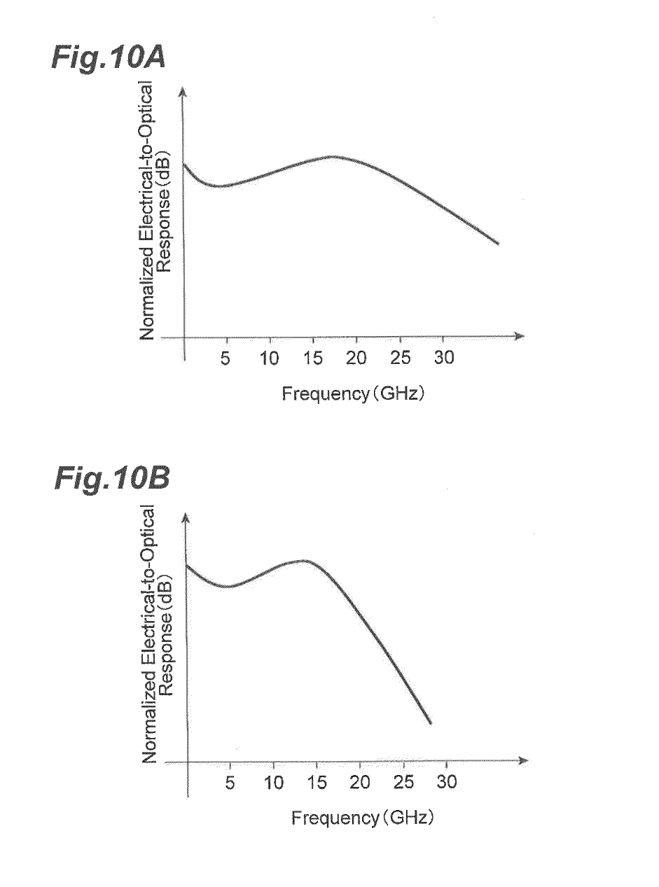

FIGS. 10A and 10B illustrate electrical-to-optical response in a laser diode which is a typical distributed-feedback (DFB) laser diode and a laser diode including a conventional driver, respectively. While the distributed-feedback laser diode is dependent on a bias current in practice, a response to a typical bias current which is assumed in normal use is illustrated as an example. As illustrated in FIG. 10A, the electrical-to-optical response of the laser diode has a lowering region (depression) of response up to near 10 GHz with its bottom located near 5 GHz and a rising region (peak) of response characteristic near 15 GHz. Reducing the depression is important for lowering the jitters in optical signals generated by the laser diode. When the laser diode is driven by a typical driver by a push-pull driving technique, the depression up to 10 GHz is not eliminated but remains as illustrated in FIG. 10B. This characteristic has a steeper gradient at 15 Ghz and above as compared with the characteristic of FIG. 10A because the wire between the driver output and the laser diode and the parasitic capacitance at the driver output produce poles.

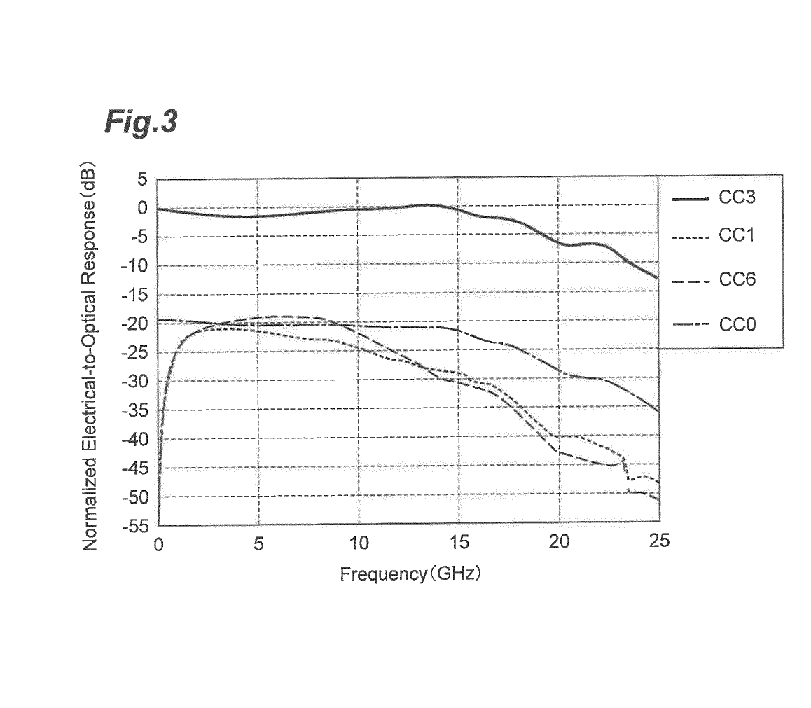

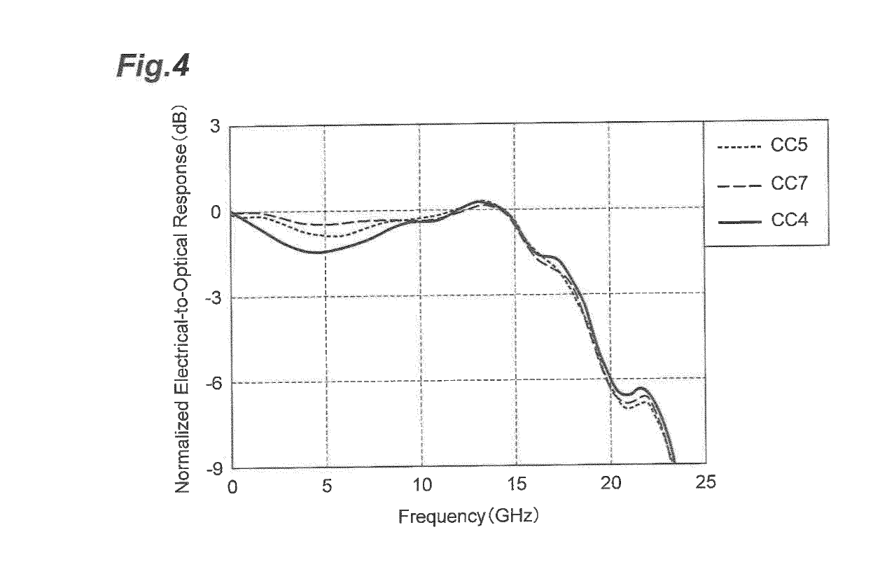

FIG. 3 illustrates electrical-to-optical response on the positive and negative phase components of the optical module 1 in accordance with the embodiment and the optical module 901 in accordance with the comparative example, while FIG. 4 illustrates electrical-to-optical response obtained by combining the positive and negative phase components of the optical module 1 in accordance with the embodiment and the optical module 901 in accordance with the comparative example. In FIG. 3, curves CC0, CC1, and CC3 indicate response of the optical module 901 on the positive phase component, optical module 1 on the positive phase component, and optical module 1, 901 on the negative phase component, respectively. On the negative phase, the optical modules 1, 901 have the same response. In FIG. 4, curves CC4 and CC5 illustrate electrical-to-optical response combining the positive phase and negative phase components of the optical modules 901, 1, respectively.

According to these responses characteristics, the optical module 901 has a substantially flat response on the positive phase from 1 GHz to 15 GHz. Here, the gradient occurring at 15 GHz and above results from the circuit such as elements and parasitic components. On the other hand, the optical module 1 has a response characteristic on the positive phase component forming a peak from near 2 GHz to near 10 GHz. In the total characteristic combining the positive phase and negative phase components, the optical module 901 has a depression from 0 GHz to 10 GHz, whereas the optical module 1 has an improved flatness by compensating the depression.

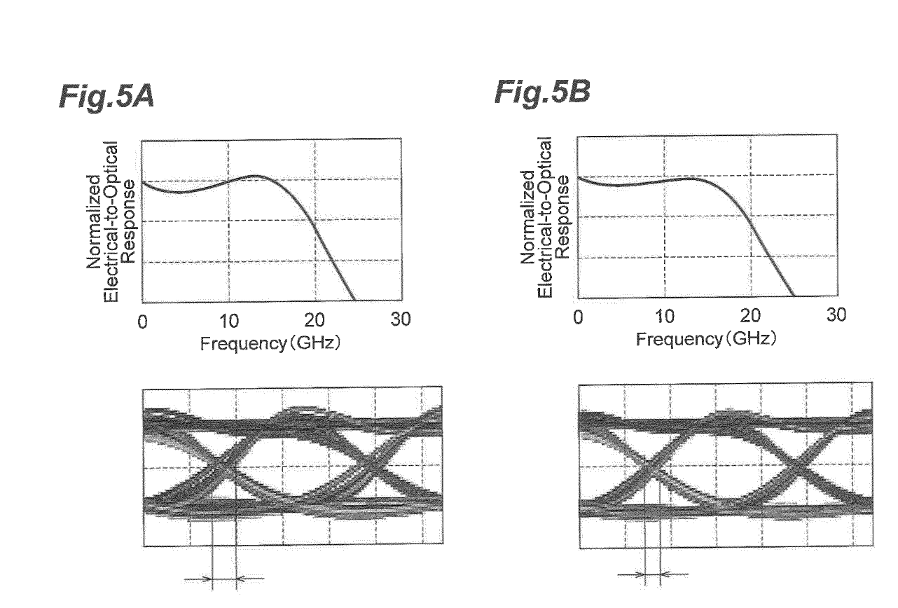

FIG. 5 illustrates results of circuit simulation of the electrical-to-optical response and the optical signal waveforms in a typical laser diode. In each of FIGS. 5A and 5B, the upper part illustrates an example of the electrical-to-optical response, while the lower part indicates eye patterns of an optical signal for the characteristic. As illustrated, when the depression up to near 10 GHz is large in the electrical-to-optical response (in the case of FIG. 5A), a jitter (width indicated by an arrow in the abscissa direction) becomes greater in the waveform of the optical output signal, thereby narrowing a part where an eye is open in the eye pattern. When the depression up to near 10 GHz is small in the electrical-to-optical response (in the case of FIG. 5B) by contrast, the jitter becomes smaller in the waveform of the optical output signal, thereby widening a part where the eye is open in the eye pattern. Such a relationship also indicates that the optical module 1 of this embodiment can reduce jitters in the optical signal waveforms, so as to output signals having a favorable quality of waveform with an improved eye pattern.

Though a preferred embodiment in accordance with the present invention is illustrated and explained in the foregoing, the present invention is not limited to the above-mentioned specific embodiment. That is, it is easy for one skilled in the art to understand various modifications and changes are possible within the scope of the gist of the present invention set forth in the claims.

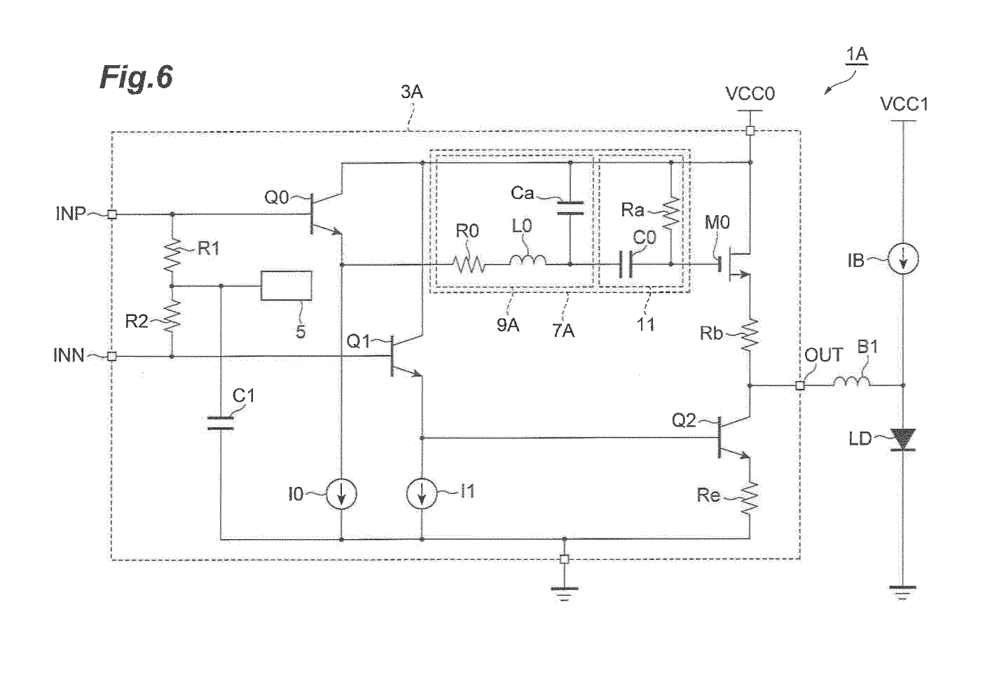

FIG. 6 illustrates the structure of an optical module 1A in accordance with a modified example of the present invention. This optical module 1A differs from the optical module 1 in the structure of a low-pass filter 9A included in a bandpass filter 7A. That is, the low-pass filter 9A comprises a resistor R0 and an inductor L0 in addition to the capacitor Ca. One end of the inductor L0 is connected through the resistor R0 to the output of the emitter follower constituted by the NPN bipolar transistor Q0 and the other end of the inductor L0 is connected through the capacitor Ca to the supply voltage VCC0. The capacitor C0 included in the high-pass filter 11 is connected between the inductor LU and the gate of the nMOS transistor M0. The resistor R0 included in the low-pass filter 9A is provided in order to lower the Q factor of the LC resonance caused by the inductor L0 and capacitor Ca. The resistance of the resistor R0, the inductance of the inductor L0, and the capacitance of the capacitor Ca are set to 3 Ω, 400 pH, and 1 pF, respectively, for example,

A characteristic curve CC6 in FIG. 3 indicates the response of the optical module 1A on the positive phase component, while a curve CC7 in FIG. 4 indicates a response combining the positive and negative phase of the optical module 1A. As illustrated in these characteristics, the optical module 1A also has a response on the positive phase component formed with a peak from near 2 GHz to near 10 GHz, while the response is further enhanced in a region from 5 GHz to 9 GHz. In the total characteristic combining the positive and negative phase sides, the optical module 1A has a further improved flatness by compensating the depression.

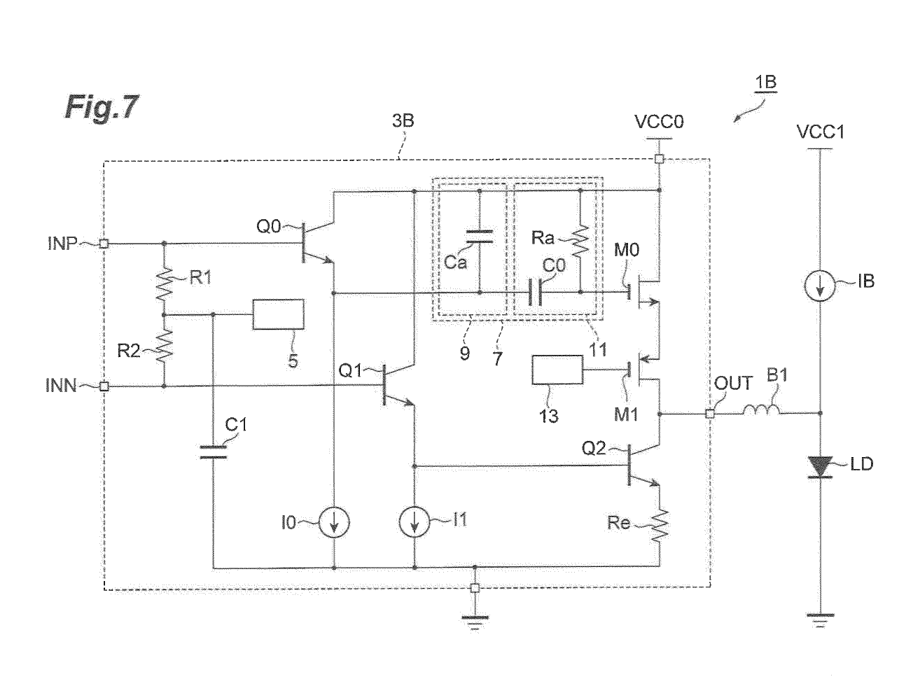

FIG. 7 illustrates the structure of an optical module 1B in accordance with a modified example of the present invention. This optical module 1B differs from the optical module 1 in that it comprises a pMOS transistor M1 and a voltage source 13 in place of the resistor Rb. The pMOS transistor M1 has a gate to which the voltage source 13 applies a bias potential Vref1, a drain connected to the output terminal OUT, and a source connected to the source of the nMOS transistor M0. Adjusting the bias potential Vref1 in such a structure enables the output resistance of the circuit including the nMOS transistor M0 on the positive phase component to have an optimal value.

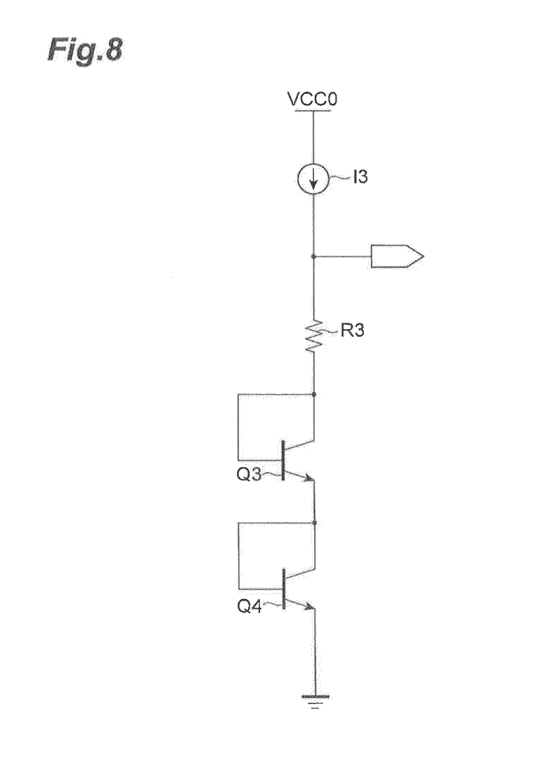

Various circuit structures can be used to constitute the voltage source 5 in FIG. 1. For example, as illustrated in FIG. 8, it may be constituted by a current source I3, a resistor R3, and NPN bipolar transistors Q3, Q4. Specifically, the collector and base of the NPN bipolar transistor Q3 are connected to the supply voltage VCC0 through the current source I3 and resistor R3. The collector and base of the NPN bipolar transistor Q4 are connected to the emitter of the NPN bipolar transistor Q3, and the emitter of the NPN bipolar transistor Q4 is grounded. The reference potential Vref0 is output from between the current source I3 and the resistor R3. The voltage source 5 provides the reference potential Vref0 by which not only the NPN bipolar transistors Q0, Q1 but also the NPN bipolar transistor Q2 are biased. The reference potential Vref0 is generated by total of voltage drops of the resistor R3 and the NPN bipolar transistor Q3, Q4 through which a current flows from the supply voltage toward the ground within an IC. The two diode-connected NPN bipolar transistors Q3, A4 are used as the load in order to generate the two voltage drops each corresponding to the base-emitter voltage Vbe of the NPN bipolar transistors Q1, Q2. The two voltage drops also have the same temperature dependence as the base-emitter voltage The of the NPN bipolar transistors Q1, Q2 so that the base voltage of the NPN bipolar transistor Q2 is maintained at an appropriate value against changes in temperature.

What is claimed is:

1. A laser driver for driving a laser diode (LD) by a differential signal having a pair of positive phase and negative phase components, the laser driver comprising:
an output terminal configured to be connected to an anode of the LD;
a first circuit configured to generate a first modulation current from the positive phase component of the differential signal and provide the first modulation current to the anode of the LD through the output terminal, the first circuit including a frequency compensator configured to boost frequency components of the positive phase component within a predetermined frequency region; and
a second circuit configured to generate a second modulation current from the negative phase component of the differential signal and provide the second modulation current to the anode of the LD through the output terminal.

2. The laser driver according to claim 1,
wherein the first circuit increases the first modulation current responding to an increase of the positive phase component;
wherein the first modulation current flows outward from the output terminal to the anode of the LD;
wherein the second circuit decreases the second modulation current responding to an increase of the negative phase component; and
wherein the second modulation current flows inward from the output terminal.

3. The laser driver according to claim 1,
wherein the first circuit further includes:
first n-type transistor configured to receive the positive phase component through the frequency compensator and output the first modulation current; and
an output resistor connected between the first n-type transistor and the output terminal;
wherein the second circuit includes a second n-type transistor configured to receive the negative phase component and output the second modulation current.

4. The laser driver according to claim 1,
wherein the frequency compensator includes:
a first filter configured to receive the positive phase component and pass frequency components of the positive phase component in a frequency region lower than a first frequency; and
a second filter configured to receive the positive phase component output from the first filter and pass frequency components of the positive phase component output from the first filter in another frequency region higher than a second frequency, the second frequency being lower than the first frequency.

5. The laser driver according to claim 1,
wherein the first circuit includes a first emitter follower configured to receive the positive phase component of the differential signal and a first n-type transistor configured to receive an output of the first emitter follower through the frequency compensator;
wherein the second circuit includes a second emitter follower configured to receive the negative phase component of the differential signal and a second n-type transistor configured to receive an output of the second emitter follower; and
wherein the frequency compensator includes:
a first filter including a first capacitor connected between an output terminal of the first emitter follower and a power supply; and
a second filter including a second capacitor and a resistor, the second capacitor being connected between the output terminal of the first emitter follower and an input terminal of the first n-type transistor, the resistor being connected between the input terminal of the first n-type transistor and the power supply.

6. The laser driver according to claim 1,
wherein the first circuit includes a first emitter follower configured to receive the positive phase component of the differential signal and a first n-type transistor configured to receive an output of the first emitter follower through the frequency compensator;
wherein the second circuit includes a second emitter follower configured to receive the negative phase component of the differential signal and a second n-type transistor configured to receive an output of the second emitter follower; and
wherein the frequency compensator includes:
a first filter including an inductor and a first capacitor, the inductor being connected between the output terminal of the first emitter follower and the first capacitor, the first capacitor being connected between the inductor and a power supply; and
a second filter including a second capacitor and a resistor, the second capacitor being connected between the inductor and an input terminal of the first n-type transistor, the resistor being connected between the input terminal of the first n-type transistor and the power supply.

7. The laser driver according to claim 6, further comprising:
a voltage source configured to provide a reference potential;
a first termination resistor connected between an input terminal of the first emitter follower and the voltage source; and
a second termination resistor connected between an input terminal of the second emitter follower and the voltage source;
wherein the second n-type transistor has a control terminal biased by a bias potential depending on the reference potential.

8. The laser driver according to claim 1,
wherein the second circuit has a gain greater than a gain of the first circuit.

9. An optical module comprising:
a laser diode (LD) configured to convert a drive current to an optical signal; and
a laser driver including,
an output terminal configured to be connected to an anode of the LD;
a first circuit configured to generate a first modulation current from the positive phase component of the differential signal and provide the first modulation current to the anode of the LD through the output terminal, the first circuit including a frequency compensator configured to boost frequency components of the positive phase component within a predetermined frequency region; and
a second, circuit configured to generate a second modulation current from the negative phase component of the differential signal and provide the second modulation current to the anode of the LD through the output terminal,
wherein the output terminal is connected to an anode of the LD, the first modulation current increasing the drive current, the second modulation current decreasing the drive current.

10. The optical module according to claim 9, further comprising:
a current source configured to provide a bias current to the anode of the LD;
wherein the drive current is determined to be a sum of the bias current and a difference between the first modulation current and the second modulation current.

11. The optical module according to claim 9,
wherein the LD has a depressed frequency response in a frequency region,
wherein the first circuit has a boosted frequency response of the positive phase component of the differential signal in the frequency region,
wherein the boosted frequency response compensates the depressed frequency response of the LD.

12. A laser driver to provide a modulation current responding to a driving signal to a laser diode (LD) through an output terminal thereof, comprising:
a first circuit and a second circuit, each of the first and second circuits being complementarily driven from the other by the driving signal,
a first transistor driven by the first circuit, the first transistor providing the modulation current outward to the output terminal; and
a second transistor driven by the second circuit, the second transistor providing the modulation current inward from the output terminal,
wherein the first circuit includes a band pass filter that cuts off high frequency components higher than a first frequency and low frequency components lower than a second frequency which is lower than the first frequency.

13. The laser driver according to the claim 12,
wherein the first transistor and the second transistor are alternately driven according to the driving signal.

14. The laser driver according to the claim 12,
wherein the first transistor provides the modulation current to the output terminal through a resistor.

15. The laser driver according to the claim 12,
wherein the band-pass filter includes a π-configuration which is constituted by a first capacitor, a second capacitor, and a resistor.

16. The laser driver according to the claim 12,
wherein the band-pass filter includes a first filter and a second filter cascaded to the first filter,
wherein the first filter includes a low-pass filter constituted by an inductor and a first capacitor,
wherein the second filter includes a high-pass filter constituted by a second capacitor and resistor.
